(19) United States
(12) Patent Application Publication
(10) Pub. No.: US 2026/0372158 A1
(43) Pub. Date: Nov. 19, 2026

(54) SEMICONDUCTOR ELEMENT AND SEMICONDUCTOR DEVICE

(71) Applicant: ROHM CO., LTD., Kyoto-shi (JP)

(72) Inventor: Masahiro MORI, Kyoto-shi (JP)

(21) Appl. No.: 19/732,215

(22) Filed: Jul. 6, 2026

Related U.S. Application Data
(63) Continuation of application No. PCT/JP2024/044547, filed on Dec. 17, 2024.

(30) Foreign Application Priority Data
Jan. 12, 2024 (JP) 2024-002929

(51) Int. Cl. H10W 72/29; H10W 72/90; H10W 74/10; H10W 90/00

(52) U.S. Cl. CPC H10W 72/29; H10W 72/932; H10W 72/934; H10W 74/137; H10W 74/147; H10W 90/724

(57) ABSTRACT

A semiconductor element includes a body including a semiconductor layer, an electrode electrically conductive to the semiconductor layer, a first contact layer electrically conductive to the electrode, a second contact layer electrically conductive to the electrode, and a terminal electrically conductive to the first contact layer and the second contact layer. The terminal is spaced apart from the electrode in a first direction with respect to the first contact layer. The first contact layer and the second contact layer are spaced apart from each other in a direction orthogonal to the first direction. As viewed in the first direction, the terminal overlaps with the first contact layer and the second contact layer.

### TECHNICAL FIELD

The present disclosure relates to a semiconductor element and a semiconductor device on which the semiconductor element is mounted.

### BACKGROUND ART

JP-2014-165335-A discloses an example of a semiconductor element, which is referred to as a semiconductor device in JP-2014-165335-A. The semiconductor element includes a substrate having an element formation surface, a pad terminal provided on the element formation surface, a Cu rewiring extending from the pad terminal, an organic coating film covering the Cu rewiring, a resin film covering the organic coating film, and an external connection terminal directly electrically connected to the Cu rewiring. The Cu rewiring includes a roughened surface resulting from the roughening process. The organic coating film is in contact with the roughened surface. Such a configuration exhibits an anchoring effect of the organic coating film to the Cu rewiring. In addition, the affinity between the organic coating film and the resin film is relatively strong, which further improves the adhesion of the resin film to the organic coating film. Thus, it is possible to suppress peeling of the resin film from the Cu rewiring layer.

In the semiconductor element disclosed in JP-2014-165335-A, the Cu rewiring is directly electrically connected to the pad terminal. If a contact area of the Cu rewiring to the pad terminal is relatively small, there may be concerns about an increase in a resistance of a conduction path from the pad terminal to the external connection terminal.

### BRIEF DESCRIPTION OF THE DRAWINGS

FIG. 1 is a partially enlarged plan view of a semiconductor element according to a first embodiment of the present disclosure, in which a second protective film, a third protective film, a terminal, and a bonding layer are shown transparently.

FIG. 2 is a sectional view taken along line II-II in FIG. 1.

FIG. 3 is a sectional view of a semiconductor device on which the semiconductor element shown in FIG. 1 is mounted.

FIG. 4 is a partially enlarged plan view of a semiconductor element according to a second embodiment of the present disclosure, in which a second protective film, a third protective film, a terminal, and a bonding layer are shown transparently.

FIG. 5 is a sectional view taken along line V-V in FIG. 4.

FIG. 6 is a partially enlarged plan view of a semiconductor element according to a third embodiment of the present disclosure, in which a second protective film, a third protective film, a terminal, and a bonding layer are shown transparently.

FIG. 7 is a partially enlarged plan view of a semiconductor element according to a fourth embodiment of the present disclosure, in which a second protective film, a third protective film, a redistribution wiring, a plurality of contact layers, a terminal, and a bonding layer are shown transparently.

FIG. 8 is a partially enlarged sectional view of a semiconductor element according to a fifth embodiment of the present disclosure.

### DETAILED DESCRIPTION

Details of the present disclosure will be described below with reference to the accompanying drawings.

### First Embodiment

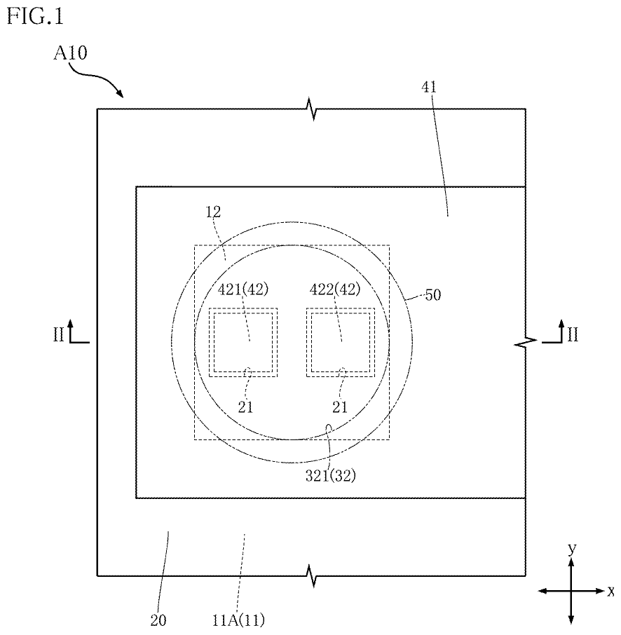

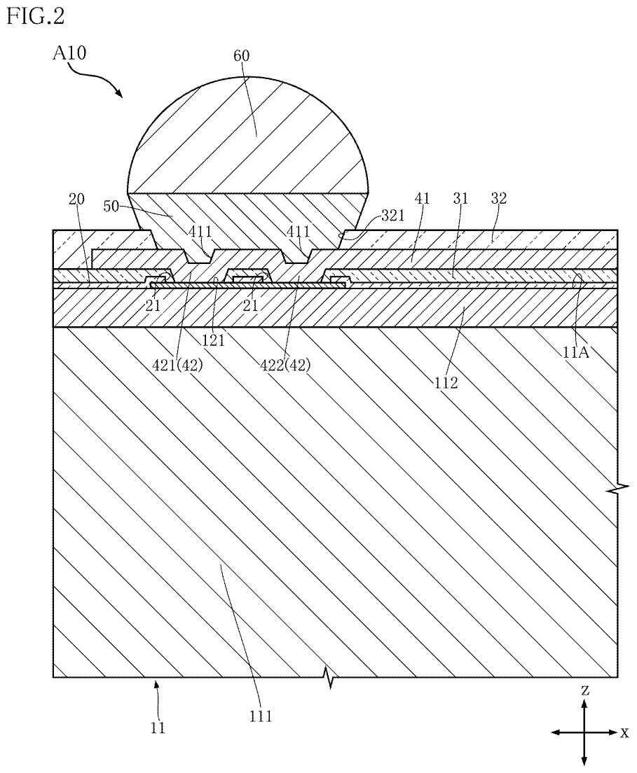

A semiconductor element A10 according to a first embodiment of the present disclosure will be described with reference to FIGS. 1 and 2. The semiconductor element A10 is, for example, an LSI (Large Scale Integration) referred to as a Wafer Level-Chip Size Package (WL-CSP). The semiconductor element A10 includes a body 11, an electrode 12, a first protective film 20, a second protective film 31, a third protective film 32, a redistribution wiring 41, a plurality of contact layers 42, a terminal 50, and a bonding layer 60. For ease of understanding, FIG. 1 shows the second protective film 31, the third protective film 32, the terminal 50, and the bonding layer 60 transparently. In FIG. 1, the third protective film 32 and the terminal 50 shown transparently are indicated by imaginary lines (two-dot chain lines).

In the description of the semiconductor element A10 and a semiconductor device B described below, for convenience, a normal direction of an obverse surface 11A described below of the body 11 is referred to as a “first direction z”. A direction orthogonal to the first direction z is referred to as a “second direction x”. A direction orthogonal to each of the first direction z and the second direction x is referred to as a “third direction y”.

As shown in FIG. 2, the body 11 includes a semiconductor substrate 111 and a semiconductor layer 112 located on a first side in the first direction z relative to the semiconductor substrate 111. The body 11 includes an obverse surface 11A facing the first side in the first direction z. The semiconductor layer 112 includes the obverse surface 11A. The semiconductor substrate 111 is formed from, for example, a silicon wafer. Various semiconductor circuits such as transistors and diodes are formed at and near the obverse surface 11A of the semiconductor layer 112.

As shown in FIG. 2, the electrode 12 is located on the first side in the first direction z relative to the body 11. The electrode 12 is in contact with the obverse surface 11A of the body 11. The electrode 12 is electrically conductive to a corresponding one of the various semiconductor circuits formed in the semiconductor layer 112. The electrode 12 contains, for example, aluminum (Al).

As shown in FIG. 2, the electrode 12 includes a connection surface 121. The connection surface 121 faces the same side as the obverse surface 11A of the body 11 in the first direction z. A part of the connection surface 121 is covered with the first protective film 20.

As shown in FIG. 2, the first protective film 20 covers the obverse surface 11A of the body 11 and a part of the electrode 12. The first protective film 20 is a thin film containing silicon dioxide (SiO₂) or silicon nitride (Si₃N₄), or a laminate of these thin films.

As shown in FIGS. 1 and 2, the first protective film 20 includes a plurality of first openings 21. Each first opening 21 extends through the first protective film 20 in the first direction z. The connection surface 121 of the electrode 12 is exposed from each first opening 21. As viewed in the first direction z, the first openings 21 are located inward of a peripheral edge of the connection surface 121.

As shown in FIG. 2, the second protective film 31 is located between the body 11 and the third protective film 32 in the first direction z. The second protective film 31 covers the first protective film 20 and a part of the electrode 12. The second protective film 31 is an insulator containing an organic compound. The second protective film 31 is made of a material containing polyimide. The second protective film 31 includes a portion located between the first protective film 20 and the redistribution wiring 41. The second protective film 31 includes a portion accommodated in each first opening 21 of the first protective film 20 and in contact with the first protective film 20 and the redistribution wiring 41.

As shown in FIG. 2, the redistribution wiring 41 is located between the contact layers 42 and the terminal 50 in the first direction z. As shown in FIG. 1, the redistribution wiring 41 extends in the second direction x. The redistribution wiring 41 is electrically conductive to the electrode 12 via the contact layers 42. The redistribution wiring 41 includes a barrier layer in contact with the second protective film 31, a seed layer laminated on the barrier layer, and a plating layer laminated on the seed layer. The barrier layer contains titanium (Ti). Each of the seed layer and the plating layer contains copper (Cu).

As shown in FIG. 2, the redistribution wiring 41 is interposed between the second protective film 31 and the third protective film 32. The redistribution wiring 41 includes a plurality of recesses 411. The recesses 411 are recessed in the first direction z from a surface of the redistribution wiring 41 facing the third protective film 32. As viewed in the first direction z, the recesses 411 individually overlap with the respective contact layers 42. The terminal 50 is received in the recesses 411.

As shown in FIG. 2, the contact layers 42 are located between the electrode 12 and the redistribution wiring 41 in the first direction z. Each contact layer 42 is directly electrically connected to the electrode 12 and the redistribution wiring 41. Accordingly, the redistribution wiring 41 and the contact layers 42 are electrically conductive to the electrode 12. Each contact layer 42 includes a barrier layer in contact with the electrode 12 and the second protective film 31, a seed layer laminated on the barrier layer, and a plating layer laminated on the seed layer. The barrier layer contains titanium. Each of the seed layer and the plating layer contains copper.

As shown in FIGS. 1 and 2, the contact layers 42 include a first contact layer 421 and a second contact layer 422. The first contact layer 421 and the second contact layer 422 are spaced apart from each other in the second direction x. At least a part of each of the first contact layer 421 and the second contact layer 422 is accommodated in a corresponding one of the first openings 21 of the first protective film 20.

As shown in FIG. 2, the third protective film 32 covers the second protective film 31 and the redistribution wiring 41. The third protective film 32 is an insulator containing an organic compound. The third protective film 32 is made of a material containing polyimide. In the semiconductor element A10, a composition of the third protective film 32 is the same as a composition of the second protective film 31. The third protective film 32 is in contact with the terminal 50. The third protective film 32 has a dimension in the first direction z greater than a dimension of the second protective film 31 in the first direction z. The third protective film 32 includes a second opening 321. The second opening 321 extends through the third protective film 32 in the first direction z. The redistribution wiring 41 is exposed from the second opening 321.

As shown in FIG. 2, the terminal 50 is located on a side opposite to the contact layers 42 with respect to the redistribution wiring 41 in the first direction z. The terminal 50 is directly electrically connected to the redistribution wiring 41. Accordingly, the terminal 50 is electrically conductive to the contact layers 42. A part of the terminal 50 is accommodated in the second opening 321 of the third protective film 32. As shown in FIG. 1, as viewed in the first direction z, the terminal 50 extends outward beyond the second opening 321. The terminal 50 is exposed from the third protective film 32. In the semiconductor element A10, a part of the terminal 50 protrudes from the third protective film 32 in the first direction z. The terminal 50 contains copper.

As shown in FIG. 1, as viewed in the first direction z, the terminal 50 overlaps with each of the first contact layer 421 and the second contact layer 422. As viewed in the first direction z, each of the first contact layer 421 and the second contact layer 422 has an area smaller than an area of the terminal 50. In the semiconductor element A10, as viewed in the first direction z, the terminal 50 overlaps with an entirety of each of the first contact layer 421 and the second contact layer 422.

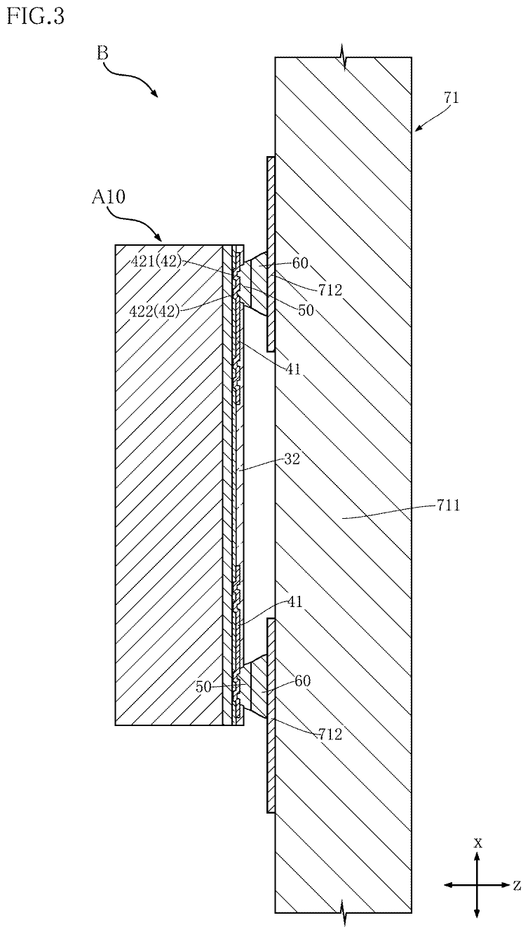

As shown in FIG. 3, the bonding layer 60 is located on a side opposite to the redistribution wiring 41 with respect to the terminal 50 in the first direction z. The bonding layer 60 is directly electrically connected to the terminal 50. The bonding layer 60 is solder. Therefore, a composition of the bonding layer 60 contains tin. A melting point of the bonding layer 60 is lower than a melting point of the terminal 50.

Next, a semiconductor device B on which the semiconductor element A10 is mounted will be described with reference to FIG. 3.

As shown in FIG. 3, the semiconductor device B includes the semiconductor element A10 and a base material 71. The semiconductor element A10 is mounted on the base material 71. The base material 71 includes a substrate 711 and a conductive portion 712. The substrate 711 is an insulator. The conductive portion 712 contains, for example, copper. Each terminal 50 of the semiconductor element A10 is conductively bonded to a corresponding conductive portion 712 via a corresponding bonding layer 60.

In the semiconductor device B, the base material 71 is a wiring board. Alternatively, the base material 71 may have a configuration including only the conductive portion 712 composed of a lead. Further, the base material 71 may have a configuration including an external terminal located on a side opposite to the conductive portion 712 with respect to the substrate 711 in the first direction z. The semiconductor device B may have a configuration including a sealing resin such as an underfill covering the semiconductor element A10.

Next, effects of the semiconductor element A10 will be described.

The semiconductor element A10 includes the body 11, the electrode 12, the first contact layer 421, the second contact layer 422, and the terminal 50. The first contact layer 421 and the second contact layer 422 are spaced apart from each other in a direction orthogonal to the first direction z. As viewed in the first direction z, the terminal 50 overlaps with each of the first contact layer 421 and the second contact layer 422. Such a configuration results in an increased sectional area of a conduction path of the semiconductor element A10 from the electrode 12 to the terminal 50 in a direction orthogonal to the first direction z. Therefore, such a configuration may reduce a resistance of the conduction path from the electrode 12 to the terminal 50 in the semiconductor element A10.

As viewed in the first direction z, each of the first contact layer 421 and the second contact layer 422 has an area smaller than an area of the terminal 50. With such a configuration, the resistance of the conduction path from the electrode 12 to the terminal 50 may be reduced without increasing a size of each of the first contact layer 421 and the second contact layer 422.

As viewed in the first direction z, the terminal 50 overlaps with an entirety of each of the first contact layer 421 and the second contact layer 422. Such a configuration may suppress an increase in length of the conduction path from the electrode 12 to the terminal 50, thereby effectively reducing the resistance of the conduction path from the electrode 12 to the terminal 50.

The redistribution wiring 41 includes the plurality of recesses 411. The terminal 50 is received in the recesses 411. Such a configuration may increase a contact area between the terminal 50 and the redistribution wiring 41, so that the resistance of the conduction path from the electrode 12 to the terminal 50 can be more effectively reduced.

### Second Embodiment

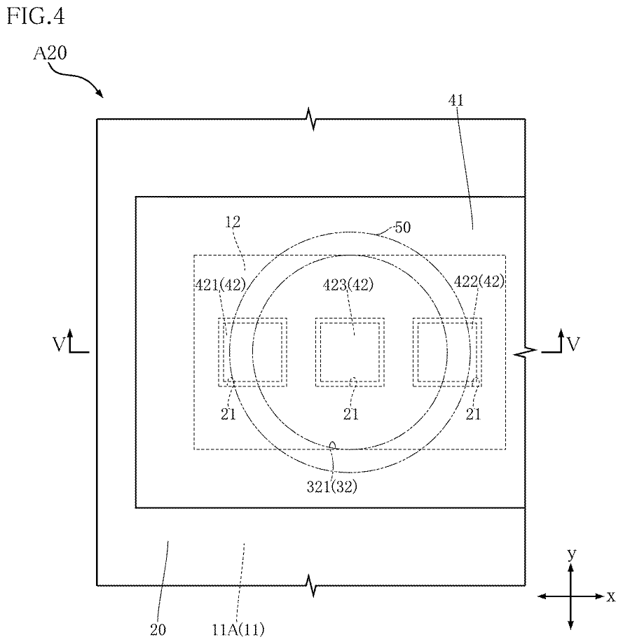

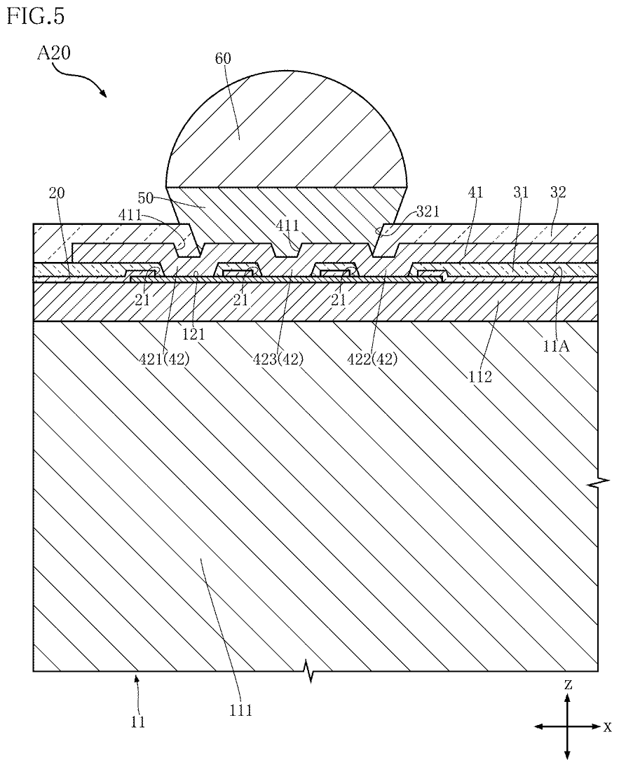

A semiconductor element A20 according to a second embodiment of the present disclosure will be described with reference to FIGS. 4 and 5. Elements identical or similar to those of the semiconductor element A10 described above are marked with the same numerals in these figures, and redundant descriptions are omitted. For ease of understanding, FIG. 4 shows the second protective film 31, the third protective film 32, the terminal 50, and the bonding layer 60 transparently. In FIG. 4, the third protective film 32 and the terminal 50 shown transparently are indicated by imaginary lines. FIG. 4 corresponds to FIG. 1 showing the semiconductor element A10.

The semiconductor element A20 differs from the semiconductor element A10 in configurations of the contact layers 42 and the third protective film 32.

As shown in FIGS. 4 and 5, the contact layers 42 include a first contact layer 421, a second contact layer 422, and a third contact layer 423. The third contact layer 423 is spaced apart from the first contact layer 421 and the second contact layer 422 in the second direction x. The third contact layer 423 is located between the first contact layer 421 and the second contact layer 422 in the second direction x.

As shown in FIG. 4, as viewed in the first direction z, each of the first contact layer 421 and the second contact layer 422 extends outward beyond the terminal 50. As viewed in the first direction z, the terminal 50 overlaps with an entirety of the third contact layer 423. As viewed in the first direction z, the third contact layer 423 has an area smaller than an area of the terminal 50.

As shown in FIG. 5, the third protective film 32 is received in at least one of the recesses 411 of the redistribution wiring 41.

Next, effects of the semiconductor element A20 will be described.

The semiconductor element A20 includes the body 11, the electrode 12, the first contact layer 421, the second contact layer 422, and the terminal 50. The first contact layer 421 and the second contact layer 422 are spaced apart from each other in a direction orthogonal to the first direction z. As viewed in the first direction z, the terminal 50 overlaps with each of the first contact layer 421 and the second contact layer 422. Therefore, such a configuration may reduce a resistance of the conduction path from the electrode 12 to the terminal 50 also in the semiconductor element A20. In addition, the semiconductor element A20 may include a configuration common to the semiconductor element A10, and therefore may achieve effects similar to those achieved by the semiconductor element A10.

The semiconductor element A20 further includes the third contact layer 423. The third contact layer 423 is spaced apart from the first contact layer 421 in a direction orthogonal to the first direction z. As viewed in the first direction z, the terminal 50 overlaps with the third contact layer 423. Such a configuration results in an increased sectional area of a conduction path of the semiconductor element A20 from the electrode 12 to the terminal 50 in a direction orthogonal to the first direction z. This further reduces the resistance of the conduction path from the electrode 12 to the terminal 50.

In the semiconductor element A20, as viewed in the first direction z, each of the first contact layer 421 and the second contact layer 422 extends outward beyond the terminal 50. Even with such a configuration, a total contact area between the contact layers 42 and the electrode 12 is increased, so that the resistance of the conduction path from the electrode 12 to the terminal 50 may be reduced as compared with conventional configurations.

In the semiconductor element A20, the third protective film 32 is received in at least one of the recesses 411 of the redistribution wiring 41. Such a configuration exhibits an anchoring effect between the third protective film 32 and the redistribution wiring 41. This suppresses peeling of the third protective film 32 from the redistribution wiring 41.

### Third Embodiment

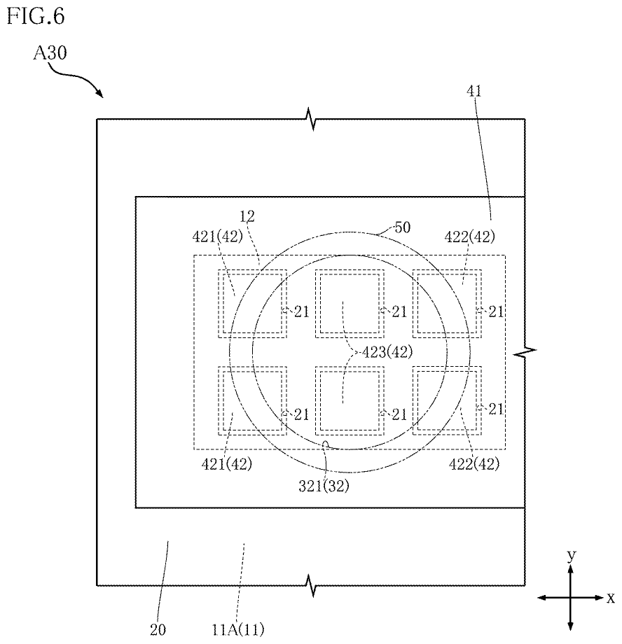

A semiconductor element A30 according to a third embodiment of the present disclosure will be described with reference to FIG. 6. Elements identical or similar to those of the semiconductor element A10 described above are marked with the same numerals in this figure, and redundant descriptions are omitted. For ease of understanding, FIG. 6 shows the second protective film 31, the third protective film 32, the terminal 50, and the bonding layer 60 transparently. In FIG. 6, the third protective film 32 and the terminal 50 shown transparently are indicated by imaginary lines. FIG. 6 corresponds to FIG. 1 showing the semiconductor element A10.

The semiconductor element A30 differs from the semiconductor element A20 in a configuration of the contact layers 42.

As shown in FIG. 6, the contact layers 42 include two first contact layers 421, two second contact layers 422, and two third contact layers 423. The two first contact layers 421 are spaced apart from each other in the third direction y. The two second contact layers 422 are spaced apart from each other in the third direction y. The two third contact layers 423 are spaced apart from each other in the third direction y. As viewed in the first direction z, each of the two first contact layers 421 and the two second contact layers 422 extends outward beyond the terminal 50. As viewed in the first direction z, an entirety of each of the two third contact layers 423 overlaps with the terminal 50.

Next, effects of the semiconductor element A30 will be described.

The semiconductor element A30 includes the body 11, the electrode 12, the first contact layer 421, the second contact layer 422, and the terminal 50. The first contact layer 421 and the second contact layer 422 are spaced apart from each other in a direction orthogonal to the first direction z. As viewed in the first direction z, the terminal 50 overlaps with each of the first contact layer 421 and the second contact layer 422. Therefore, such a configuration may reduce a resistance of the conduction path from the electrode 12 to the terminal 50 also in the semiconductor element A30. In addition, the semiconductor element A30 may include a configuration common to the semiconductor element A10, and therefore may achieve effects similar to those achieved by the semiconductor element A10.

The semiconductor element A30 includes two first contact layers 421, two second contact layers 422, and two third contact layers 423. With such a configuration, in the conduction path of the semiconductor element A30 from the electrode 12 to the terminal 50, a sectional area in a direction orthogonal to the first direction z is further increased as compared with the semiconductor element A20. This further reduces the resistance of the conduction path from the electrode 12 to the terminal 50 as compared with the semiconductor element A20.

### Fourth Embodiment

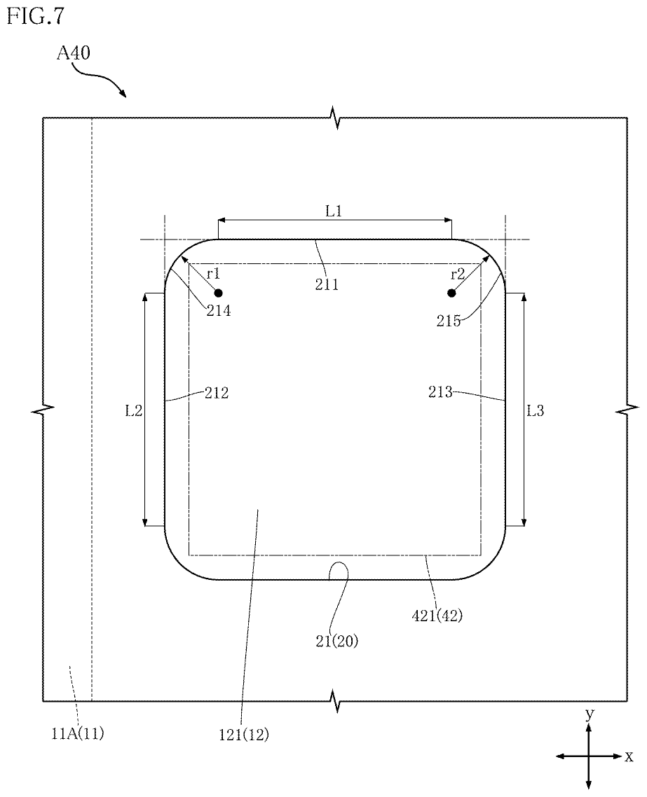

A semiconductor element A40 according to a fourth embodiment of the present disclosure will be described with reference to FIG. 7. Elements identical or similar to those of the semiconductor element A10 described above are marked with the same numerals in this figure, and redundant descriptions are omitted. For ease of understanding, FIG. 7 shows the second protective film 31, the third protective film 32, the redistribution wiring 41, the contact layers 42, the terminal 50, and the bonding layer 60 transparently. In FIG. 7, the contact layers 42 shown transparently are indicated by imaginary lines.

The semiconductor element A40 differs from the semiconductor element A10 in a configuration of the first protective film 20.

As shown in FIG. 7, as viewed in the first direction z, a peripheral edge of each of the first openings 21 includes a first edge 211, a second edge 212, a third edge 213, a first connecting edge 214, and a second connecting edge 215. The first edge 211 extends in the second direction x. Each of the second edge 212 and the third edge 213 extends in the third direction y. Hence, a direction in which each of the second edge 212 and the third edge 213 extends is different from a direction in which the first edge 211 extends. The third edge 213 is located on a side opposite to the second edge 212 with the first edge 211 interposed therebetween. The first edge 211, the second edge 212, and the third edge 213 have lengths L1, L2, and L3, respectively, and each of the lengths L2 and L3 is equal to or less than the length L1. In the semiconductor element A40, each of the lengths L2 and L3 is equal to the length L1.

As shown in FIG. 7, the first connecting edge 214 is connected to the first edge 211 and the second edge 212. The first connecting edge 214 is curved. The first connecting edge 214 has a radius of curvature r1 not less than 20% of the length L1 of the first edge 211. As viewed in the first direction z, the first connecting edge 214 is spaced apart from an extension line of the first edge 211 and an extension line of the second edge 212.

As shown in FIG. 7, the second connecting edge 215 is connected to the first edge 211 and the third edge 213. The second connecting edge 215 is curved. The second connecting edge 215 has a radius of curvature r2 not less than 20% of the length L1 of the first edge 211. In the semiconductor element A40, the radius of curvature r2 is equal to the radius of curvature r1 of the first connecting edge 214. As viewed in the first direction z, the second connecting edge 215 is spaced apart from an extension line of the first edge 211 and an extension line of the third edge 213.

Next, effects of the semiconductor element A40 will be described.

The semiconductor element A40 includes the body 11, the electrode 12, the first contact layer 421, the second contact layer 422, and the terminal 50. The first contact layer 421 and the second contact layer 422 are spaced apart from each other in a direction orthogonal to the first direction z. As viewed in the first direction z, the terminal 50 overlaps with each of the first contact layer 421 and the second contact layer 422. Therefore, such a configuration may reduce a resistance of the conduction path from the electrode 12 to the terminal 50 also in the semiconductor element A40. In addition, the semiconductor element A40 may include a configuration common to the semiconductor element A10, and therefore may achieve effects similar to those achieved by the semiconductor element A10.

In the semiconductor element A40, as viewed in the first direction z, the peripheral edge of the first opening 21 includes the first edge 211, the second edge 212, and the first connecting edge 214. The second edge 212 extends in a direction different from a direction in which the first edge 211 extends. The first connecting edge 214 is curved. During use of the semiconductor element A40, thermal stress caused by heat conducted from the body 11 to the electrode 12 is applied to the first protective film 20. In view of this, such a configuration may reduce concentration of thermal stress applied to the peripheral edge of the first opening 21. This can suppress generation of cracks in the first protective film 20.

In addition to the configuration described above, the length L2 of the second edge 212 is equal to or less than the length L1 of the first edge 211. The radius of curvature r1 of the first connecting edge 214 is not less than 20% of the length L1. Such a configuration may effectively reduce concentration of thermal stress applied to the peripheral edge of the first opening 21.

### Fifth Embodiment

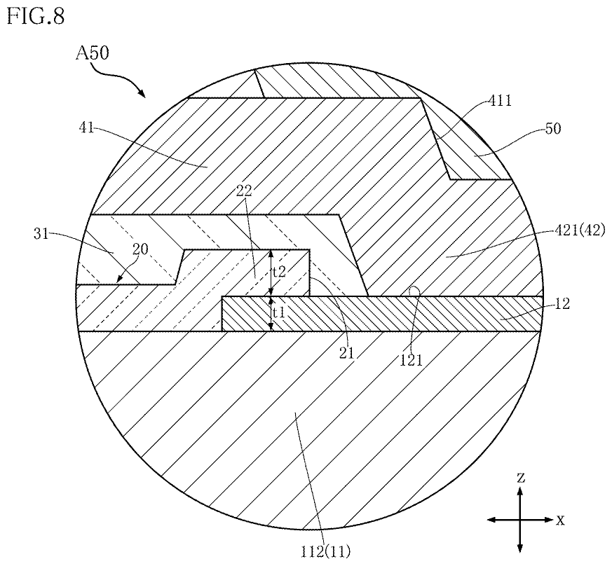

A semiconductor element A50 according to a fifth embodiment of the present disclosure will be described with reference to FIG. 8. Elements identical or similar to those of the semiconductor element A10 described above are marked with the same numerals in this figure, and redundant descriptions are omitted.

The semiconductor element A50 differs from the semiconductor element A10 in a configuration of the first protective film 20.

As shown in FIG. 8, the first protective film 20 includes a covering portion 22 covering the electrode 12. As viewed in the first direction z, an entirety of the covering portion 22 overlaps with the electrode 12. The covering portion 22 has a dimension t2 in the first direction z greater than a dimension t1 of the electrode 12 in the first direction z.

Next, effects of the semiconductor element A50 will be described.

The semiconductor element A50 includes the body 11, the electrode 12, the first contact layer 421, the second contact layer 422, and the terminal 50. The first contact layer 421 and the second contact layer 422 are spaced apart from each other in a direction orthogonal to the first direction z. As viewed in the first direction z, the terminal 50 overlaps with each of the first contact layer 421 and the second contact layer 422. Therefore, such a configuration may reduce a resistance of the conduction path from the electrode 12 to the terminal 50 also in the semiconductor element A50. In addition, the semiconductor element A50 may include a configuration common to the semiconductor element A10, and therefore may achieve effects similar to those achieved by the semiconductor element A10.

In the semiconductor element A50, the first protective film 20 includes the covering portion 22 covering the electrode 12. As viewed in the first direction z, an entirety of the covering portion 22 overlaps with the electrode 12. The dimension t2 of the covering portion 22 in the first direction z is greater than the dimension t1 of the electrode 12 in the first direction z. During use of the semiconductor element A50, thermal stress caused by heat conducted from the body 11 to the electrode 12 is applied to the first protective film 20. In view of this, such a configuration may reduce concentration of thermal stress in the covering portion 22, thereby suppressing generation of cracks in the first protective film 20.

The present disclosure is not limited to the above-described embodiments. Specific configurations of each part of the present disclosure may be modified in various ways.

The present disclosure includes embodiments described in the following clauses.

### Clause 1

A semiconductor element comprising:
a body including a semiconductor layer;
an electrode located on a first side in a first direction relative to the body and electrically conductive to the semiconductor layer;
a first contact layer and a second contact layer electrically conductive to the electrode; and
a terminal located on a side opposite to the electrode in the first direction with respect to the first contact layer and electrically conductive to the first contact layer and the second contact layer,
wherein the first contact layer and the second contact layer are spaced apart from each other in a direction orthogonal to the first direction, and
as viewed in the first direction, the terminal overlaps with each of the first contact layer and the second contact layer.

### Clause 2

The semiconductor element according to clause 1, wherein, as viewed in the first direction, each of the first contact layer and the second contact layer has an area smaller than an area of the terminal.

### Clause 3

The semiconductor element according to clause 2, wherein, as viewed in the first direction, the terminal overlaps with an entirety of each of the first contact layer and the second contact layer.

### Clause 4

The semiconductor element according to clause 2, wherein, as viewed in the first direction, the first contact layer extends outward beyond the terminal.

### Clause 5

The semiconductor element according to clause 4, wherein, as viewed in the first direction, the second contact layer extends outward beyond the terminal.

### Clause 6

The semiconductor element according to clause 2, further comprising a third contact layer electrically conductive to the electrode,
wherein the third contact layer is spaced apart from the first contact layer in a direction orthogonal to the first direction,
as viewed in the first direction, the terminal overlaps with the third contact layer, and
as viewed in the first direction, the third contact layer has an area smaller than the area of the terminal.

### Clause 7

The semiconductor element according to any one of clauses 2 to 6, wherein the first contact layer and the second contact layer are directly electrically connected to the electrode.

### Clause 8

The semiconductor element according to clause 7, further comprising a first protective film located on the same side as the electrode with respect to the body and covering a part of the electrode and the body,
wherein the first protective film includes a plurality of first openings extending through the first protective film in the first direction, the electrode being exposed from each of the plurality of first openings, and
at least a part of each of the first contact layer and the second contact layer is accommodated in a corresponding one of the plurality of first openings.

### Clause 9

The semiconductor element according to clause 8, wherein the first protective film contains at least one of silicon dioxide and silicon nitride.

### Clause 10

The semiconductor element according to clause 9, wherein, as viewed in the first direction, each of the plurality of first openings includes a peripheral edge including a first edge, a second edge, and a first connecting edge that is connected to the first edge and the second edge, each of the first edge and the second edge extending in a direction orthogonal to the first direction,
the second edge extends in a direction different from a direction in which the first edge extends, and
the first connecting edge is curved.

### Clause 11

The semiconductor element according to clause 10, wherein, as viewed in the first direction, the first connecting edge is spaced apart from an extension line of the first edge and an extension line of the second edge.

### Clause 12

The semiconductor element according to clause 11, wherein the second edge has a length equal to or less than a length of the first edge, and
the first connecting edge has a radius of curvature not less than 20% of the length of the first edge.

### Clause 13

The semiconductor element according to clause 9, wherein the first protective film includes a covering portion covering the electrode,
as viewed in the first direction, an entirety of the covering portion overlaps with the electrode, and
the covering portion has a dimension in the first direction greater than a dimension of the electrode in the first direction.

### Clause 14

The semiconductor element according to clause 9, further comprising:
a second protective film covering the first protective film; and
a redistribution wiring located between the first contact layer and the terminal in the first direction,
wherein the redistribution wiring is directly electrically connected to the first contact layer, the second contact layer, and the terminal, and
the second protective film includes a portion interposed between the first protective film and the redistribution wiring.

### Clause 15

The semiconductor element according to clause 14, wherein the second protective film includes a portion accommodated in each of the plurality of first openings and in contact with the first protective film.

### Clause 16

The semiconductor element according to clause 15, further comprising a third protective film covering the second protective film and the redistribution wiring,
wherein the third protective film is in contact with the terminal, and
the terminal is exposed from the third protective film.

### Clause 17

The semiconductor element according to clause 16, wherein the third protective film includes a second opening extending through the third protective film in the first direction, the redistribution wiring being exposed from the second opening, and
a part of the terminal is accommodated in the second opening.

### Clause 18

The semiconductor element according to clause 17, wherein a part of the terminal protrudes from the second opening, and
as viewed in the first direction, the terminal extends outward beyond the second opening.

### Clause 19

The semiconductor element according to clause 18, further comprising a bonding layer directly electrically connected to the terminal,
wherein the bonding layer is located on a side opposite to the redistribution wiring with respect to the terminal, and
the bonding layer has a melting point lower than a melting point of the terminal.

### Clause 20

A semiconductor device comprising:
the semiconductor element according to clause 7; and
a base material including a conductive portion,
wherein the semiconductor element is mounted on the base material, and
the terminal is conductively bonded to the conductive portion.

### Clause 21

The semiconductor element according to clause 11, wherein the second edge extends in a direction orthogonal to a direction in which the first edge extends.

### Clause 22

The semiconductor element according to clause 21, wherein, as viewed in the first direction, the peripheral edge of the first opening includes a third edge and a second connecting edge connected to the first edge and the third edge, the third edge being located on a side opposite to the second edge with the first edge interposed therebetween,
the third edge extends in the same direction as the second edge, and
the second connecting edge is curved.

### Clause 23

The semiconductor element according to clause 22, wherein the third edge has a length equal to or less than a length of the first edge, and
the second connecting edge has a radius of curvature not less than 20% of the length of the first edge.

### Clause 24

The semiconductor element according to clause 16, wherein the redistribution wiring includes a plurality of recesses recessed in the first direction from a side on which the terminal is located in the first direction,
as viewed in the first direction, the plurality of recesses overlap with the first contact layer and the second contact layer, respectively, and
the terminal is received in the plurality of recesses.

### Clause 25

The semiconductor element according to clause 24, wherein the third protective film is received in at least one of the plurality of recesses.

### Clause 26

The semiconductor element according to clause 16, wherein each of the second protective film and the third protective film contains polyimide.

### Clause 27

The semiconductor element according to clause 16, wherein the third protective film has a dimension in the first direction greater than a dimension of the second protective film in the first direction.

1. A semiconductor element comprising:
a body including a semiconductor layer;
an electrode located on a first side in a first direction relative to the body and electrically conductive to the semiconductor layer;
a first contact layer and a second contact layer electrically conductive to the electrode; and
a terminal located on a side opposite to the electrode in the first direction with respect to the first contact layer and electrically conductive to the first contact layer and the second contact layer,
wherein the first contact layer and the second contact layer are spaced apart from each other in a direction orthogonal to the first direction, and
as viewed in the first direction, the terminal overlaps with each of the first contact layer and the second contact layer.

2. The semiconductor element according to claim 1, wherein, as viewed in the first direction, each of the first contact layer and the second contact layer has an area smaller than an area of the terminal.

3. The semiconductor element according to claim 2, wherein, as viewed in the first direction, the terminal overlaps with an entirety of each of the first contact layer and the second contact layer.

4. The semiconductor element according to claim 2, wherein, as viewed in the first direction, the first contact layer extends outward beyond the terminal.

5. The semiconductor element according to claim 4, wherein, as viewed in the first direction, the second contact layer extends outward beyond the terminal.

6. The semiconductor element according to claim 2, further comprising a third contact layer electrically conductive to the electrode,
wherein the third contact layer is spaced apart from the first contact layer in a direction orthogonal to the first direction,
as viewed in the first direction, the terminal overlaps with the third contact layer, and
as viewed in the first direction, the third contact layer has an area smaller than the area of the terminal.

7. The semiconductor element according to claim 2, wherein the first contact layer and the second contact layer are directly electrically connected to the electrode.

8. The semiconductor element according to claim 7, further comprising a first protective film located on the same side as the electrode with respect to the body and covering a part of the electrode and the body,
wherein the first protective film includes a plurality of first openings extending through the first protective film in the first direction, the electrode being exposed from each of the plurality of first openings, and
at least a part of each of the first contact layer and the second contact layer is accommodated in a corresponding one of the plurality of first openings.

9. The semiconductor element according to claim 8, wherein the first protective film contains at least one of silicon dioxide and silicon nitride.

10. The semiconductor element according to claim 9, wherein, as viewed in the first direction, each of the plurality of first openings includes a peripheral edge including a first edge, a second edge, and a first connecting edge connected to the first edge and the second edge, each of the first edge and the second edge extending in a direction orthogonal to the first direction,
the second edge extends in a direction different from a direction in which the first edge extends, and
the first connecting edge is curved.

11. The semiconductor element according to claim 10, wherein, as viewed in the first direction, the first connecting edge is spaced apart from an extension line of the first edge and an extension line of the second edge.

12. The semiconductor element according to claim 11, wherein the second edge has a length equal to or less than a length of the first edge, and
the first connecting edge has a radius of curvature not less than 20% of the length of the first edge.

13. The semiconductor element according to claim 9, wherein the first protective film includes a covering portion covering the electrode,
as viewed in the first direction, an entirety of the covering portion overlaps with the electrode, and
the covering portion has a dimension in the first direction greater than a dimension of the electrode in the first direction.

14. The semiconductor element according to claim 9, further comprising:
a second protective film covering the first protective film; and
a redistribution wiring located between the first contact layer and the terminal in the first direction,
wherein the redistribution wiring is directly electrically connected to the first contact layer, the second contact layer, and the terminal, and
the second protective film includes a portion interposed between the first protective film and the redistribution wiring.

15. The semiconductor element according to claim 14, wherein the second protective film includes a portion accommodated in each of the plurality of first openings and in contact with the first protective film.

16. The semiconductor element according to claim 15, further comprising a third protective film covering the second protective film and the redistribution wiring,
wherein the third protective film is in contact with the terminal, and
the terminal is exposed from the third protective film.

17. The semiconductor element according to claim 16, wherein the third protective film includes a second opening extending through the third protective film in the first direction, the redistribution wiring being exposed from the second opening, and
a part of the terminal is accommodated in the second opening.

18. The semiconductor element according to claim 17, wherein a part of the terminal protrudes from the second opening, and
as viewed in the first direction, the terminal extends outward beyond the second opening.

19. The semiconductor element according to claim 18, further comprising a bonding layer directly electrically connected to the terminal,
wherein the bonding layer is located on a side opposite to the redistribution wiring with respect to the terminal, and
the bonding layer has a melting point lower than a melting point of the terminal.

20. A semiconductor device comprising:
the semiconductor element according to claim 7; and
a base material including a conductive portion,
wherein the semiconductor element is mounted on the base material, and
the terminal is conductively bonded to the conductive portion.
